(19) United States
(12) Patent Application Publication
(10) Pub. No.: US 2005/0205963 A1
(43) Pub. Date: Sep. 22, 2005

(54) Integrated anneal cap/ ion implant mask/ trench isolation structure for III-V devices

(76) Inventors: David Alan Johnson, Colorado Springs, CO (US); Charles W. Jurgensen, Colorado Springs, CO (US)

Correspondence Address: David A. Johnson, 7945 Ruststone Ct., Colorado Springs, CO, 80919, US

(21) Appl. No.: 10/801,431

(22) Filed: Mar. 16, 2004

(51) Int. Cl. H01L 21/76; H01L 29/00

(52) U.S. Cl. 257/510

(57) ABSTRACT

A structure with significant topography enhancements over the traditional composite dielectric structure is provided. Topography reduction at this level of the device structure significantly enhances critical dimension control of subsequent device patterns through reduced depth of focus requirements during lithography, and reduced over-etch requirements.

### CROSS-REFERENCE TO RELATED APPLICATIONS

N/A

### STATEMENT REGARDING FEDERALLY SPONSORED RESEARCH OR DEVELOPMENT

This Invention was not conceived, constructed, or tested during the performance of a government contract.

### REFERENCE TO SEQUENCE LISTING, A TABLE, OR A COMPUTER PROGRAM LISTING COMPACT DISK APPENDIX

N/A

### BACKGROUND OF THE INVENTION

1. Field of Invention

The present invention relates broadly to III-V semiconductor devices, and in particular, an improved isolation structure for such devices.

2. Description of the Prior Art

The composite dielectric layer used in the fabrication of III-V devices, disclosed in U.S. Pat. No. 5,001,076, has been instrumental in yielding high levels of integration on such semiconductors. As transistor densities increase, and dimensions decrease, there becomes an increasing trade-off between the ability of the dielectric layer to mask ion implantations, and topography resulting from patterning of the composite layer.

Traditionally mesa-type isolation structures of III-V bipolar transistors are defined after the patterning of the emitter and other device layers as described on p. 375 of S. M. Sze, “High-Speed Semiconductor Devices”, Wiley, New York, 1990. The resulting isolation topography greatly complicates the interconnect of these devices. High levels of device integration have not been achieved for III-V bipolar transistors with these isolation last process integration schemes.

Structures, often referred to as “shallow trench isolation” used in silicon processing to reduce topography rely on silicon specific etches, thermal oxidation to round the trench corners, and do not provide the necessary capping layer required by III-V semiconductors. Examples of these isolation structures are given is U.S. Pat. Nos. 6,500,726; 6,479,369; 6,452,246; 6,177,333; 6,069,057; 6,054,343; 4,980,306; 4,836,885; 4,837,178; 6,265,743. Such structures are also not compatible with III-V semiconductors, and they require the use of a wet etch to remove the final dielectric covering the active regions. Wet etches have disadvantages such as high interfacial etch rates resulting in increased defect densities.

Isolation structures using oxygen implants, or oxygen doped epitaxial layers such as those disclosed in U.S. Pat. Nos. 5,482,872 and 5,844,303, exhibit higher leakage currents and higher parasitic capacitance.

Groove isolation structures as disclosed in U.S. Pat. No. 5,293,061 do not provide the planarity necessary for defining subsequent fine geometries.

Structures created for silicon substrates with some components similar to those compatible with III-V compounds such as that disclosed in U.S. Pat. No. 6,441,444 require a thermal oxidation step, and subsequent thermal nitridation steps that are incompatible with III-V compounds.

### BRIEF SUMMARY OF THE INVENTION

A trench structure used to isolate III-V devices, as well as act as an anneal cap and ion implant mask is produced with the following procedure:
1. Defining active regions of semiconductor (10) by etching areas (12) around the active regions (11) with a III-V semiconductor etch process leaving the cross-section shown in FIG. 1.
2. Depositing a dielectric layer on the wafer suitable for both an anneal cap and CMP stop (13), then depositing a gap fill layer (14) as shown in FIG. 2. For devices requiring ion implantation, the combination of the gap fill layer, and the anneal cap/CMP stop layer may also be used as an ion implant stop
3. Polishing the Gap fill layer, and some of the CMP stop layer, leaving the cross-section shown in FIG. 3.
4. Removing the CMP stop layer (13) from the top of the III-V semiconductor with an etch selective to the III-V semiconductor, leaving a cross-section shown in FIG. 4.

The resulting structure is significantly more planar than the traditional composite dielectric structure used with III-V VLSI devices. This structure allows for reduced device-level metal capacitance, low active area to active area leakage, and topography reduction compared to conventional III-V bipolar structures. Finally, this structure is compatible with III-V semiconductors, and allows for use of a dry etch for removal of the final dielectric layer over the active semiconductor, where traditional silicon structures do not.

### BRIEF DESCRIPTION OF THE SEVERAL VIEWS OF THE DRAWING

FIG. 1 is a schematic sectional view of the partially fabricated isolation structure after the isolation etch step.

FIG. 2 is a schematic sectional view of the partially fabricated isolation structure after the deposition of the combination anneal cap layer, and the gap fill layer.

FIG. 3 is a schematic sectional view of the partially fabricated isolation structure after the polishing of the gap fill layer, and part of the combination anneal cap layer.

FIG. 4 is a schematic sectional view of the complete isolation structure.

### DETAILED DESCRIPTION OF THE INVENTION

While the description below is specifically directed to gallium arsenide (GaAs) devices, it will be appreciated that other III-V devices will similarly benefit from the teachings of the invention.

### First Embodiment

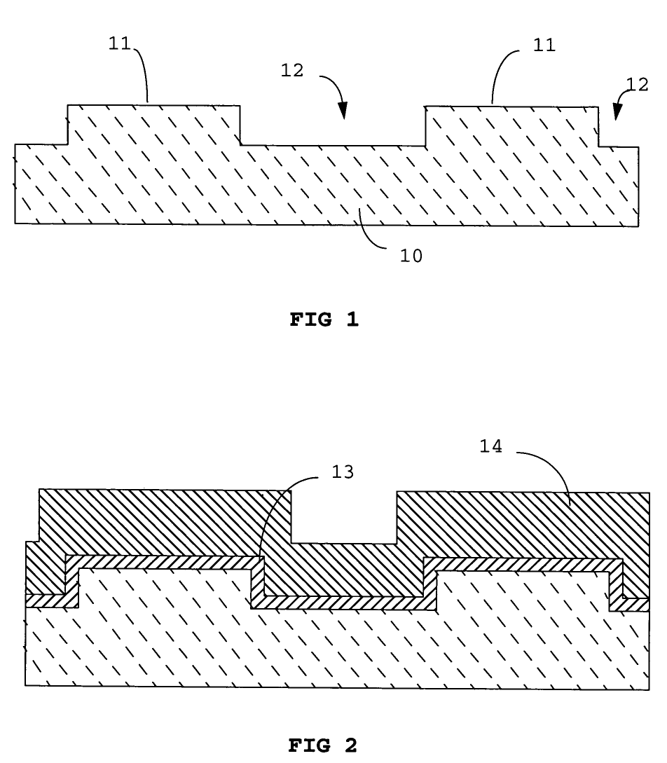

The GaAs wafer (10) shown in FIG. 1 is either semi-insulating (near intrinsic), or is doped of the opposite type to be used in the outer portions of the active regions (11).

The wafer is patterned with conventional photolithographic means, and an etch that leaves 500 A-5000 A deep isolation trenches in the GaAs. The FIG. 1 drawing shows sharp bottom corners, but the GaAs etch used at this step will need to round these corners to a degree dictated by the modulus of the gap fill material, and the temperature of subsequent anneals used.

An optional background implant may be done at this point.

Next silicon nitride (13) is deposited on the semiconductor as a combination anneal cap layer, and a CMP stop layer. The thickness of this layer is typically 5-25% of the depth of the trench etched, but specifically depends on the uniformities and selectivities of the subsequent process steps.

A silicon dioxide gap fill layer (14) is deposited on top of the anneal cap layer at a thickness greater than the depth of the isolation trenches.

An optional anneal may be done at this point to activate the optional background implant, and/or prepare the gap fill material for further processing.

An optional photolithographic step is done at this point essentially matching the pattern of that used to define the isolation trenches, but with the image reversed. If this optional photolithographic step is performed, then it is followed by an etch that removes the gap fill dielectric (14) over most of the active region area (11).

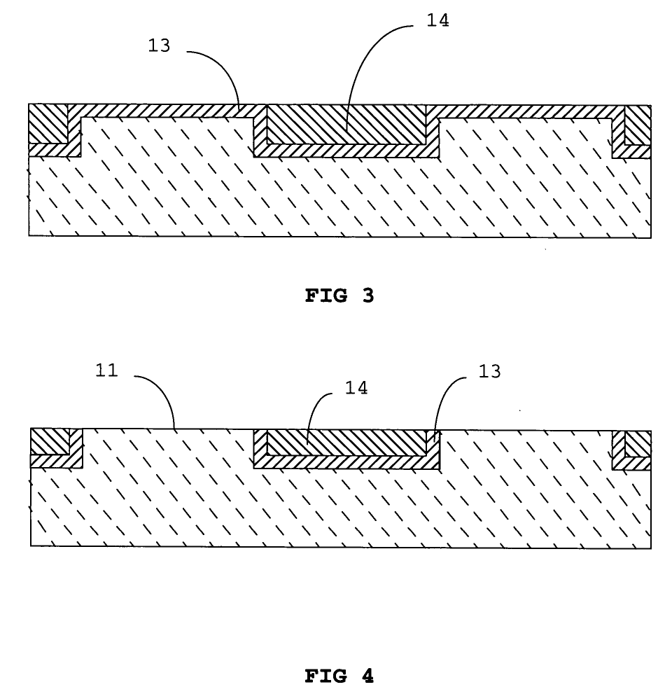

The remaining gap fill dielectric (14) above the active area anneal cap layer (13) is removed with a conventional chemical mechanical polish process resulting in the FIG. 3 cross-section.

The anneal cap is removed from the active regions with an etch selective to GaAs such as a low energy NF3 plasma. This will leave a surface that is planar to the degree of the thickness of the anneal cap layer. The final active area (11)/isolation region (12) step height will depend on the etch selectivity of the anneal cap removal etch to the gap fill material, and the effect of subsequent etching on the device. The aggregate of these processes may be matched for near perfect planarity as shown in FIG. 4.

The remaining portion of the circuit may then be fabricated on top of the planar surface without concern of device leakage caused by uncapped semiconductor in the isolation regions, and without concern of device leakage caused by implanting active species between the active regions.

### Second Embodiment

The GaAs wafer shown in FIG. 1 comprising a substrate, and device epitaxial layers grown on top. Device epitaxial layers may be those used for forming HBT devices, HEMT devices, optimized MESFET devices, or other devices.

To electrically isolate active regions of the wafers, the wafer is patterned with conventional photolithographic means, and an etch that removes the active layers of the wafer in the isolation regions (12). Depending on the epitaxial structure of the starting material, the depth of these trenches may be anywhere from 500 A to several microns.

Next, silicon nitride (13) is deposited on the semiconductor as a combination anneal cap layer, and a CMP stop layer. The thickness of this layer is typically 5-25% of the depth of the trench etched, but specifically depends on the uniformities and selectivities of the subsequent process steps.

A silicon dioxide gap fill layer (14) is deposited on top of the anneal cap layer at a thickness larger than the depth of the isolation trenches.

An optional anneal may be done at this point to prepare the gap fill material for further processing.

An optional photolithographic step is done at this point essentially matching the pattern of that used to define the isolation trenches (12), but with the image reversed. If this optional photolithographic step is performed, then it is followed by an etch that removes the gap fill dielectric (14) over most of the active region area.

The remaining gap fill dielectric above the active area anneal cap layer is removed with a conventional chemical mechanical polish process.

The anneal cap (13) is removed from the active regions with an etch selective to the top epitaxial layer such as a low energy NF3 plasma. This will leave a surface that is planar to the degree of the thickness of the anneal cap layer. The final active area/isolation region step height will depend on the selectivity of the anneal cap removal etch to the gap fill material, and the effect of subsequent etching on the device. The aggregate of these processes may be matched for near perfect planarity as shown in FIG. 4.

The remaining portion of the circuit may then be fabricated on top of the planar surface without concern of device leakage caused by uncapped semiconductor in the isolation regions, remaining active layers between active regions, or implanting active species between the active regions.

1. A structure providing anneal cap, ion implant mask, and shallow trench isolation features for III-V devices comprising a trench etched into the semiconductor, a combination anneal cap/CMP stop layer, and a dielectric trench fill layer, with significant topography reduction compared to the traditional composite dielectric structure.

2. The multipurpose structure of claim 1, where said III-V semiconductor is GaAs.

3. The multipurpose structure of claim 1, where said III-V semiconductor is InP

4. The multipurpose structure of claim 1, where said III-V semiconductor is GaAs with over-layers of other semiconductors specific to the devices fabricated.

5. The multipurpose structure of claim 1, where said III-V semiconductor is InP with over-layers of other semiconductors specific to the devices fabricated.

6. The multipurpose structure of claim 1, where said combination anneal cap/CMP stop layer is 100-3000 A of silicon nitride.

7. The multipurpose structure of claim 1, where said combination anneal cap/CMP stop layer is silicon nitride with a thickness 5 to 25 percent of the trench depth to facilitate CMP processing.

8. The multipurpose structure of claim 1, where said dielectric trench fill layer is silicon dioxide.
